(19) United States
(12) Patent Application Publication
(10) Pub. No.: US 2025/0015677 A1
(43) Pub. Date: Jan. 9, 2025

(54) METHOD FOR CALCULATION OF A MECHNICAL SPEED OF AN ELECTRIC ROTATIONAL MACHINE

(71) Applicant: Danfoss Power Electronics A/S, Gråsten (DK)

(72) Inventors: Jörg Dannehl, Chapel Hill, NC (US); Luzia Almeida, Nordborg (DK)

(21) Appl. No.: 18/761,807

(22) Filed: Jul. 2, 2024

(30) Foreign Application Priority Data
Jul. 4, 2023 (DE) 102023117624.2

(51) Int. Cl. H02K 11/21

(52) U.S. Cl. CPC H02K 11/21; H02K 2213/03; H02K 2213/06

(57) ABSTRACT

A method (100) for calculation of a mechanical speed of an electric rotational machine (400) including calculating (101) a frequency spectrum from signals measured by at least one vibration sensor (403) attached to the rotational machine (400); extracting (103) a mechanical speed component from the calculated frequency spectrum; calculating (105) the mechanical speed of the rotational machine (400) as a function of the mechanical speed component, wherein the mechanical speed component is extracted as a function of a frequency component that is greater than a given threshold (303).

### CROSS-REFERENCE TO RELATED APPLICATION

This application claims foreign priority benefits under 35 U.S.C. § 119 to German Patent Application No. 102023117624.2 filed on Jul. 4, 2023, the content of which is hereby incorporated by reference in its entirety.

### TECHNICAL FIELD

The invention disclosed herein relates to a method for calculation of a mechanical speed of an electric rotational machine and to an electric rotational machine according to the attached claims.

### BACKGROUND

Vibration monitoring is a known condition monitoring technique for rotating machines. It is based on accelerometers or piezoelectric sensors mounted on the machine.

Advanced monitoring methods often deploy frequency spectrum analytics to detect and diagnose a type of the fault. For example, a misalignment of the motor shaft leads to characteristic peaks in a flowchart of a radial movement over the order of rotation of a rotational machine.

For fault classification there is a need to know the actual speed of a rotor of the rotational machine to identify the relevant peaks, since different faults, i.e. unbalance, eccentricity etc., result in different measurement fault patterns. However, the frequencies of the fault pattern are typically relative to the rotational speed.

Further, it is known to use rotor position estimation techniques in frequency converters to control a speed of a motor. For the estimation of the speed of the motor, electric signals, such as current and voltages, are fed into a mathematical motor model that outputs the estimated position of the rotor. Parameters of the mathematical motor model are typically being measured during commissioning. Thus, a problem arises in that the parameters of the mathematical model can be inaccurate, and they can change over time during operation due to changing temperature wear of the motor, breakdown of windings and/or change in motor load for instance, which leads to inaccurate results, i.e. an inaccurate estimation of the motor speed.

Against this background, there is need for an accurate calculation of the motor speed of an electric rotational machine.

### SUMMARY

Thus, according to a first aspect of the present invention, there is disclosed a method for calculation of a mechanical speed of an electric rotational machine.

The method according to the present invention comprises accelerating the motor speed, calculating the frequency spectrum of the signal measured by at least one vibration sensor attached to the rotational machine, extracting a mechanical speed component from the calculated frequency spectrum, and calculating the mechanical speed of the rotational machine as a function of the mechanical speed component, wherein the mechanical speed component is extracted as a function of a frequency component that is greater than a given threshold.

In the context of the present invention, a mechanical speed component is to be understood as a mathematical expression that changes relative to the speed of a rotor of an electric rotational machine. In particular, a mechanical speed component may be mathematical expression that describes a level of unbalance, misalignment or eccentricity, which is practically present in every application, even though it is not considered faulty but just normal. The mathematical expression may be based or contain peaks in frequency spectrum patterns that are relative to the rotational speed of the motor.

By using a mechanical speed component, the speed of a rotational machine can be calculated very accurate. Further, the mechanical speed component may vary over time according to changing characteristics of the rotational machine. Thus, by periodically calculating the speed of a rotational machine using a mechanical speed component, the changing characteristics of the rotational machine are included in the calculation of the speed of the rational machine, resulting a very accurate information about the state, i.e. the speed of the rotational machine. Accordingly, parameters of a mathematical motor model of the rotational machine that are measured during commissioning of the rotational machine can be updated in order to generate an accurate mathematical motor model that represents the current state of the rotational machine.

By extracting a mechanical speed component as a function of a frequency component that is greater than a given threshold, only significant vibrations are used as indicators for the speed of the rotational machine. Accordingly, influences of background noise not related to the speed of the rotational machine on the calculated mechanical speed are minimized.

In order to calculate the mechanical speed of the rotational machine as a function of the mechanical speed component, a value of an extracted mechanical speed component may be as such be used as the mechanical speed or the value may be mathematically transformed into a rotational speed or angular speed, or a corresponding index value for example.

According to an embodiment, the threshold is a multiple, in particular a triple, of an average of a plurality of frequencies of the frequency spectrum.

By calculating the threshold for extracting the mechanical speed component from the frequency spectrum dynamically, i.e. based on a plurality of frequencies of the frequency spectrum, in particular each frequency of the frequency spectrum, situations in which the threshold is too high or too low can be avoided. In particular, a threshold being a triple, of an average of all frequencies of the frequency spectrum has been found as being sufficient for identification of representative mechanical speed components.

According to another embodiment, the threshold is a multiple, in particular a triple, of a standard deviation of frequencies of the frequency spectrum.

By taking into account the standard deviation for calculation of the threshold, the influence of extreme values on the threshold is minimized such that the threshold represents an overall behavior of the rotational machine.

According to another embodiment, the mechanical speed component is extracted as a function of a plurality of frequencies that are greater than a given threshold.

By taking into account a plurality of frequencies for calculation of the mechanical speed, multiple mechanical origins, such as multiple deformations at multiple spots on the rotational machine can be used for a very accurate calculation of the mechanical speed.

According to another embodiment, the method further comprises estimating a rotor position of a rotor of the rotational machine as a function of at least one electric parameter measured during operation of the rotational machine, determining an estimated motor speed based on the estimated rotor position, and minimizing a difference between the mechanical speed and the estimated motor speed by adjusting control parameters of the rotational machine.

According to another embodiment, the difference between the mechanical speed and the estimated motor speed is minimized by adjusting the control parameters of the rotational machine such that the estimated motor speed approaches to the calculated mechanical speed.

In order to control the rotational machine based on the calculated mechanical speed, the control parameters can be adjusted based on a difference between the calculated mechanical speed and an estimated motor speed used in a control loop for controlling the rotational machine.

Thus, an accelerometer signal is may be used to adjust the motor model parameters during operation.

The adjustment may be based on a frequency spectrum analysis algorithm, which provides ac-curate motor model parameters that adapt to any operational condition. On one side of the algorithm a frequency spectrum analysis of the accelerometer signal is node to extract an accurate measurement of the mechanical speed of the rotational machine. On the other side, an estimated rotor position is used to derive an estimated rotor speed. Then the difference between the calculated motor speed and the estimated rotor speed is calculated. Based on the difference the motor parameters are adjusted in such a way that the difference is minimized.

According to another embodiment, the mechanical speed is fed into a mathematical motor model of the rotational machine for controlling the rotational machine.

By feeding the mechanical speed into a mathematical motor model, the mathematical motor model will automatically adopt itself to control the rotational machine based on the calculated mechanical speed and, therefore, very accurate.

According to another embodiment, a plurality of frequency spectra from multiple signals measured by multiple vibration sensors attached at various locations at the rotational machine are used and the mechanical speed is calculated as a function of the mechanical speed component having the greatest value and/or the smallest variance.

By using multiple vibration sensors, the best spot for measuring a signal representative for the speed of the rotational machine can be found.

According to another embodiment, the calculated mechanical speed is sent to a safety function as a redundant speed feedback signal.

By using a redundant signal, a failure in estimating of the main signal can be identified. Further, by using the mechanical speed for control of the rotational machine instead of the main signal, the rotational machine can be further operated in case of a failure for estimating the main signal.

According to another embodiment, a fault message is output in case a difference between the calculated mechanical speed and a speed calculated based on a signal measured by an encoder and/or a resolver is greater than a tolerance threshold.

By using the calculated mechanical speed as a reference, a faulty speed signal may identified easily. Thus, in case a faulty speed signal is identified, the sensor underlying the faulty speed signal has to be faulty as well.

According to a second aspect, the present invention relates to an electric rotational machine. The rotational machine comprises a rotor, a number of vibration sensors, and a processor, wherein the processor is configured to carry out an embodiment of the method disclosed herein.

According to an embodiment, the number of vibration sensors are part of a monitoring system.

By using of vibration sensors are part of a monitoring system as the vibrations sensor for calculation of the mechanical speed, the vibration sensors have a double function. Thus, in case of a rotational machine that is equipped with a vibration sensor based monitoring system, no addition-al sensors are necessary for carrying out the method disclosed herein.

According to another embodiment, the number of vibration sensors comprises at least one acceleration sensor.

In particular, acceleration sensors have been found as being suitable for identification of speed related signals due to specific vibrations of a gearbox or a belt, for example.

According to another embodiment, the electric rotational machine does not comprise an encoder and/or a resolver.

By using the method or the machine disclosed herein, the speed of the machine can be calculated very precisely. Thus, additional sensors, such as an encoder and/or a resolver are not need-ed.

The effects and further embodiments of the estimation of the method for estimation of a mechanical speed of an electric rotational machine according to the present invention are analogous to the effects and embodiments of the enclosure according to the description mentioned above. Thus, it is referred to the above description of the enclosure.

### BRIEF DESCRIPTION OF THE DRAWINGS

Further features, details and advantages of the invention result from the wording of the claims as well as from the following description of exemplary embodiments based on the drawings. The figures show:

FIG. 1 an embodiment of the method disclosed herein,

FIG. 2 a schematic overview of an algorithm based on the method disclosed herein,

FIG. 3 a schematic overview of the principle underlying the method disclosed herein,

FIG. 4 an embodiment of the electric rotational machine disclosed herein.

### DETAILED DESCRIPTION

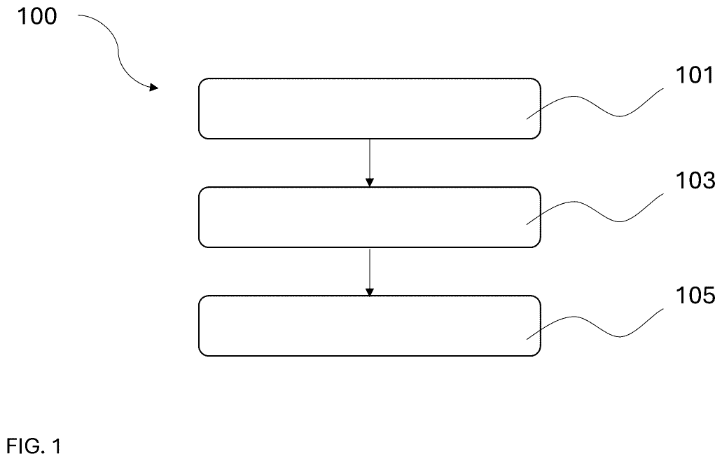

In FIG. 1, a method 100 for calculation of a mechanical speed of an electric rotational machine is shown.

The method 100 comprises a first calculation step 101, in which a frequency spectrum is calculated from signals measured by at least one vibration sensor attached to the rotational machine.

Further, the method 100 comprises an extraction step 103, in which a mechanical speed component is extracted from the calculated frequency spectrum, wherein the mechanical speed component is extracted as a function of a frequency that is greater than a given threshold.

Further, the method 100 comprises a second calculation step 105, in which the mechanical speed of the rotational machine is calculated as a function of the mechanical speed component.

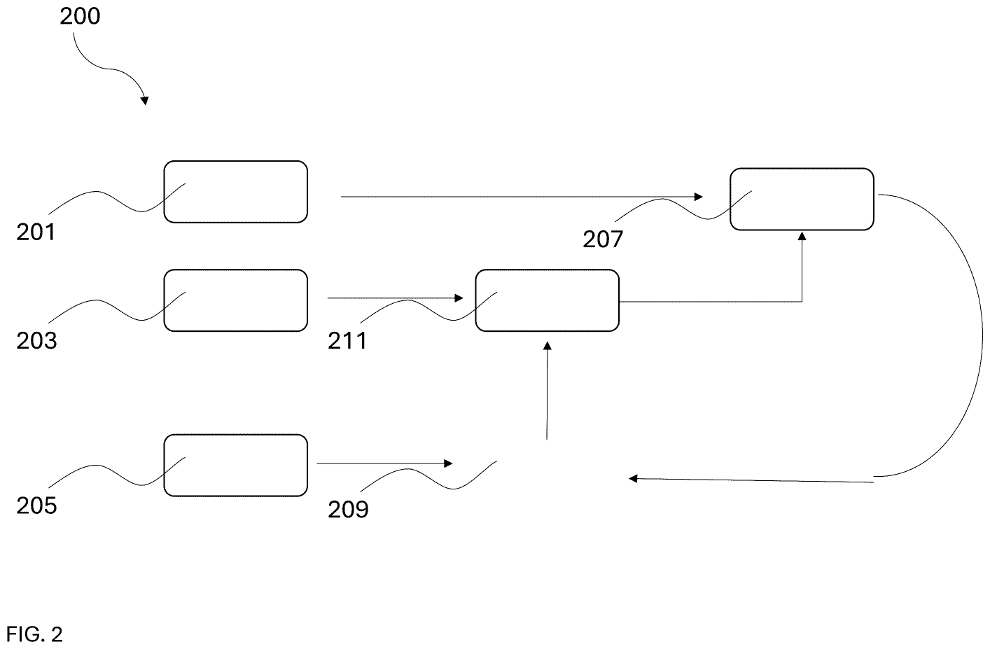

In FIG. 2, an algorithm 200 is shown. The algorithm 200 is based on electrical motor signals 201, such as currents and/or voltages, initial motor model parameters 203 and acceleration signals 205 measured by acceleration sensors attached on the rotational machine, as input signals.

Based on the electric motor signals 201, a rotor position estimation 207 is carried out using the motor model parameters 203.

Based on the acceleration signals 205, a frequency spectrum analysis 209 is carried out using the method 100 according to FIG. 1. The mechanical speed calculated in the frequency spectrum analysis 209 is brought in a mathematical relation to the rotor position estimated in the rotor position estimation 207, by transforming the estimated rotor position into an estimated rotor speed and by further subtracting the estimated rotor speed from the calculated mechanical speed or vice versa, for example.

The result of the frequency spectrum analysis 209 is used for online motor parameter adaption 211 of the mathematical motor model. Thus, the rotor position estimation 207 can be carried out a second time using accurate motor model parameters.

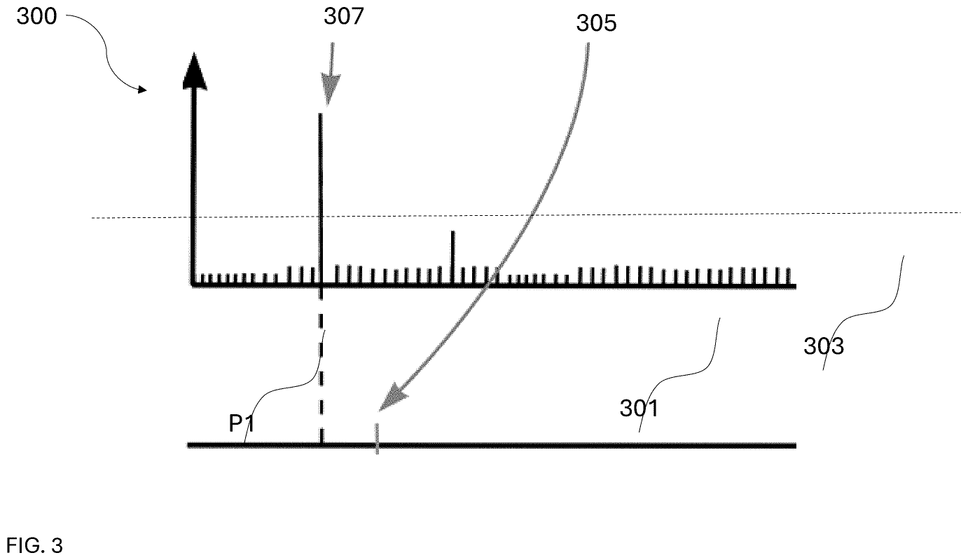

In FIG. 3, a graph 300 is shown having a frequency on its x-axis and an acceleration index on its y-axis.

Parameters 301 are calculated from a signal measured by an acceleration sensor attached to a rotational machine. At position P1, a large value 307 can be seen, which is larger than a thresh-old 303 and, therefore, represents a mechanical speed component.

Since the mechanical speed component correlates with the real speed of the rotational machine, a mechanical speed of the rotational machine can be calculated based on the value of the mechanical speed component.

As soon as the mechanical speed is calculated, it can be brought into a mathematical relation to an estimated speed value 305 calculated based on an estimated position of the rotor of the rotational machine. The result of the mathematical relation, which may be a division or a subtraction, is used in a feedback loop for parameter adjustment in a mathematical motor model for controlling a motor of the rotational machine.

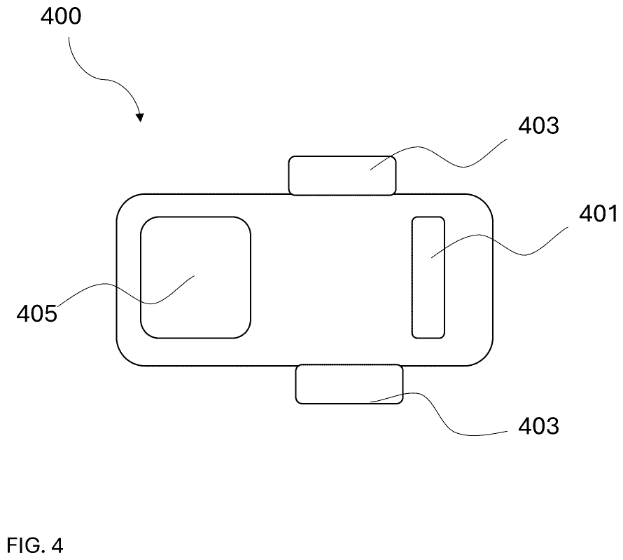

In FIG. 4, an electric rotational machine 400 is shown. The rotational machine 400 comprises a rotor 401, a number of vibration sensors 403, and a processor 405.

The processor 405 is configured to carry out the method 100 according to FIG. 1.

The invention is not limited to one of the aforementioned embodiments. It can be modified in many ways.

All features and advantages resulting from the claims, the description and the drawing, including constructive details, spatial arrangements and procedural steps, may be essential for the invention both in themselves and in various combinations.

While the present disclosure has been illustrated and described with respect to a particular embodiment thereof, it should be appreciated by those of ordinary skill in the art that various modifications to this disclosure may be made without departing from the spirit and scope of the present disclosure.

1. A method for calculation of a mechanical speed of an electric rotational machine,
the method comprising:
calculating a frequency spectrum from signals measured by at least one vibration sensor attached to the rotational machine,
extracting a mechanical speed component from the calculated frequency spectrum,
calculating the mechanical speed of the rotational machine as a function of the mechanical speed component,
wherein the mechanical speed component is extracted as a function of a frequency component that is greater than a given threshold.

2. The method according to claim 1,
wherein
the threshold is a multiple, in particular a triple, of an average of a plurality of frequencies of the frequency spectrum.

3. The method according to claim 1,
wherein
the threshold is a multiple, in particular a triple, of a standard deviation of frequencies of the frequency spectrum.

4. The method according to claim 1,
wherein
the mechanical speed component is extracted as a function of a plurality of frequencies that are greater than the threshold.

5. The method according to claim 1,
wherein
the method further comprises:
estimating a rotor position of a rotor of the rotational machine as a function of at least one electric parameter measured during operation of the rotational machine,
determining an estimated motor speed based on the estimated rotor position,
minimizing a difference between the mechanical speed and the estimated motor speed by adjusting control parameters of the rotational machine.

6. The method according to claim 5,
wherein
the difference between the mechanical speed and the estimated motor speed is minimized by adjusting the control parameters of the rotational machine such that the estimated motor speed approaches to the calculated mechanical speed.

7. The method according to claim 5,
wherein
the mechanical speed is fed into a mathematical motor model of the rotational machine for controlling the rotational machine.

8. The method according to claim 1,
wherein
a plurality of frequency spectra from multiple signals measured by multiple vibration sensors attached at various locations at the rotational machine are used and the mechanical speed is calculated as a function of the mechanical speed component having the greatest value and/or the smallest variance.

9. The method according to claim 1,
wherein
the calculated mechanical speed is sent to a safety function as a redundant speed feed-back signal.

10. The method according to claim 1,
wherein
a fault message is output in case a difference between the calculated mechanical speed and a speed calculated based on a signal measured by an encoder and/or a resolver is greater than a tolerance threshold.

11. An electric rotational machine,
the rotational machine comprising:
a rotor,
a number of vibration sensors,
a processor,
wherein the processor is configured to carry out the method according to claim 1.

12. The electric rotational machine according to claim 11,
wherein
the number of vibration sensors are part of a monitoring system.

13. The electric rotational machine according to claim 11,
wherein
the number of vibration sensors comprises at least one acceleration sensor.

14. The electric rotational machine according to claim 11,
wherein
the electric rotational machine does not comprise an encoder and/or a resolver.

15. The method according to claim 2,
wherein
the mechanical speed component is extracted as a function of a plurality of frequencies that are greater than the threshold.

16. The method according to claim 3,
wherein
the mechanical speed component is extracted as a function of a plurality of frequencies that are greater than the threshold.

17. The method according to claim 2,
wherein
the method further comprises:
estimating a rotor position of a rotor of the rotational machine as a function of at least one electric parameter measured during operation of the rotational machine,
determining an estimated motor speed based on the estimated rotor position,
minimizing a difference between the mechanical speed and the estimated motor speed by adjusting control parameters of the rotational machine.

18. The method according to claim 3,
wherein
the method further comprises:
estimating a rotor position of a rotor of the rotational machine as a function of at least one electric parameter measured during operation of the rotational machine,
determining an estimated motor speed based on the estimated rotor position,
minimizing a difference between the mechanical speed and the estimated motor speed by adjusting control parameters of the rotational machine.

19. The method according to claim 4,
wherein
the method further comprises:
estimating a rotor position of a rotor of the rotational machine as a function of at least one electric parameter measured during operation of the rotational machine,
determining an estimated motor speed based on the estimated rotor position,
minimizing a difference between the mechanical speed and the estimated motor speed by adjusting control parameters of the rotational machine.

20. The method according to claim 6,
wherein
the mechanical speed is fed into a mathematical motor model of the rotational machine for controlling the rotational machine.
